(19) United States
(12) Patent Application Publication
(10) Pub. No.: US 2005/0029091 A1
(43) Pub. Date: Feb. 10, 2005

(54) Apparatus and method for reactive sputtering deposition

(76) Inventors: Chan Park, Changwon-City (KR); Do-Jun Youm, Yuseong-Gu (KR); Ho-Sup Kim, Kimhae-City (KR); Kook-Chae Chung, Seo-Gu (KR); Byung-Su Lee, Yeosu-City (KR); Sun-Me Lim, Yuseong-Gu (KR)

Correspondence Address: CANTOR COLBURN, LLP, 55 GRIFFIN ROAD SOUTH, BLOOMFIELD, CT, 06002, US

(21) Appl. No.: 10/895,560

(22) Filed: Jul. 21, 2004

(30) Foreign Application Priority Data
Jul. 21, 2003 (KR) 2003-49669
Jul. 20, 2004 (KR) 2004-56207

(51) Int. Cl. C23C 14/32

(52) U.S. Cl. 204/192.15; 204/298.11

(57) ABSTRACT

Disclosed herein is a reactive sputtering deposition apparatus in which a partition plate is provided between a sputtering target and a substrate. The reactive sputtering deposition apparatus comprises a deposition chamber for creating an inner process atmosphere of the apparatus, a target including a metal material to be deposited, a substrate on which a reaction product of the metal material separated from the target with a reactive gas is deposited, and a partition plate dividing the deposition chamber into a reaction chamber at the side of the substrate and a sputtering chamber at the side of the target and provided between the target and the substrate, wherein an opening is formed through a central portion of the partition plate to allow the metal material separated from the target to reach the substrate. According to the reactive sputtering deposition apparatus, the transfer of the reactive gas to the metal target is minimized and thus the oxidation of the metal target is prevented, thereby enabling deposition of a metal oxide thin film on the substrate at a high rate. Further disclosed is a reactive sputtering deposition method using the apparatus.

### BACKGROUND OF THE INVENTION

1. Field of the Invention

The present invention relates to an apparatus and a method for reactive sputtering deposition. More particularly, the present invention relates to a reactive sputtering deposition apparatus in which a partition plate is provided between a sputtering target and a substrate, thereby enabling deposition of a metal oxide on the substrate at a high rate, and a reactive sputtering deposition method using the apparatus.

2. Description of the Related Art

Chemical vapor deposition (CVD), sputtering deposition, molecular beam epitaxial (MBE) deposition and E-beam deposition methods have been used to deposit metal oxide thin films on substrates. Among these deposition methods, the sputtering deposition method is one wherein a metal material separated from a metal target by using an argon gas plasma, etc., is deposited on a substrate.

Depending on the constituent materials of a target, deposition methods for forming a metal oxide thin film on a substrate by sputtering are largely divided into the following two types, i.e., use of a metal oxide ceramic as a target material, and a reactive sputtering deposition. However, since the former type has a problem of low deposition rate, it is not suitable for practical application. According the latter type, a metal material separated from a target is transformed into a product having a different chemical structure by, e.g., oxidation, and is then deposited on a substrate.

In the reactive sputtering deposition, characteristics of a thin film to be deposited are varied depending on the partial pressure of oxygen to be supplied. When the partial pressure of oxygen is too low, the metal material to be deposited on a substrate cannot be sufficiently oxidized to form a thin film having a desired phase. Meanwhile, when the partial pressure of oxygen is too high, oxidation takes place on a target surface, causing low deposition rate.

Accordingly, in order to deposit a metal oxide thin film at a high rate by reactive sputtering deposition, it is required that the oxidation of a metal target should be prevented, and at the same time, a target material to be deposited on a substrate should sufficiently react with a reactive gas. Moreover, the substrate, particularly metal substrate, should not react with the reactive gas until the target material is deposited on the substrate.

FIG. 1 is a graph showing changes in the deposition rate of a metal oxide thin film by reactive sputtering with increasing partial pressures of oxygen. The dotted line divides the graph into a metal deposition region and an oxide deposition region. Specifically, when the partial pressure of oxygen is too low, a metal material of a thin film to be deposited is not sufficiently oxidized and thus the metal material itself is deposited on a substrate. On the other hand, when the partial pressure of oxygen is too high, a target is easily oxidized and thus the deposition rate tends to decrease sharply. However, in the case where the vacuum atmosphere of a chamber is appropriately maintained and the structure of the chamber is appropriately constructed, there exists a zone, i.e., a process window (W), over a wide area in which the deposition rate is uniformly maintained without a decrease in the deposition rate despite increased partial pressures of oxygen in the oxide deposition region. In this area, a metal oxide thin film is suitably deposited by reactive sputtering.

In order to satisfy these conditions, a reactive sputtering deposition apparatus must be suitably configured, and a reactive gas must be chosen so as to be suitable for the process.

### SUMMARY OF THE INVENTION

Therefore, the present invention has been made in view of the above problems, and it is an object of the present invention to provide a reactive sputtering deposition apparatus enabling deposition of a metal oxide thin film on a substrate at a high rate by reactive sputtering.

It is another object of the present invention to provide a reactive sputtering deposition method enabling deposition of a metal oxide thin film on a substrate at a high rate by reactive sputtering.

It is another object of the present invention to provide a reactive sputtering deposition apparatus in which a partition plate is provided between a target and a substrate.

It is another object of the present invention to provide a reactive sputtering deposition method using the reactive sputtering deposition apparatus.

It is another object of the present invention to provide a reactive sputtering deposition apparatus wherein a reactive gas is injected in the vicinity of a substrate and a sputtering gas is injected in the vicinity of a metal target, thereby accelerating oxidation of a metal target material to be deposited on the substrate and preventing oxidation of the metal target.

It is still another object of the present invention to provide a reactive sputtering deposition method using the apparatus.

In order to accomplish the above objects of the present invention, there is provided a reactive sputtering deposition apparatus, comprising: a deposition chamber for creating an inner process atmosphere of the apparatus; a target including a metal material to be deposited; a substrate on which a reaction product of the metal material separated from the target with a reactive gas is deposited; and a partition plate dividing the deposition chamber into a reaction chamber at the side of the substrate and a sputtering chamber at the side of the target and provided between the target and the substrate, wherein an opening is formed through a central portion of the partition plate to allow the metal material separated from the target to reach the substrate. According to the apparatus of the present invention, the transfer of the reactive gas to the metal target is minimized and thus the oxidation of the metal target is prevented, thereby enabling deposition of a metal oxide thin film on the substrate at a high rate.

According to one embodiment of the apparatus of the present invention, the reactive sputtering deposition apparatus further comprises an exhaust port adapted to create a vacuum atmosphere, the exhaust vent being arranged at the reaction chamber to face a back surface of the substrate. The sputtering chamber is preferably arranged beneath the reaction chamber. In addition, the reactive sputtering deposition apparatus may further comprise a reactive gas supply tube for supplying a reactive gas to the reaction chamber so as to form a metal oxide film on the substrate through a reaction of the reactive gas with the metal material, the reactive gas supply tube being arranged at the reaction chamber. The reactive gas supply tube is preferably arranged toward the substrate in a direction opposite to the target. The reactive sputtering deposition apparatus may further comprise a reactive gas reservoir may be arranged at the substrate side of the reactive gas supply tube wherein a slot having a relatively large length with respect to its width is formed at the reactive gas reservoir along a length direction of the substrate, and the reactive gas is temporarily stored in the reactive gas reservoir before being injected into the substrate so as to retain a high energy. According to the apparatus of the present invention, the transfer of the reactive gas to the target is prevented, thus reducing oxidation of the target. The reactive gas used herein is oxygen, water vapor, hydrogen and a mixed gas thereof.

According to another embodiment of the apparatus of the present invention, the reactive sputtering deposition apparatus further comprises a cover surrounding the target material of the target and a sputtering gas supply tube for injecting a sputtering gas between the target material and the cover. The sputtering gas used herein is an inert gas, a reducing gas or a mixed gas thereof. The reducing gas is preferably hydrogen gas. The use of the sputtering gas prevents oxidation of the target material.

In accordance with another aspect of the present invention, there is provided a reactive sputtering deposition apparatus for depositing a reaction product of a metal material separated from a target with a reactive gas on a substrate, the reactive sputtering deposition apparatus comprising a reactive gas supply tube for supplying the reactive gas to a reaction chamber so as to form a metal oxide film on the substrate through a reaction of the reactive gas with the metal material, and a reactive gas reservoir arranged at the substrate side of the reactive gas supply tube, wherein a slot having a relatively large length with respect to its width is formed at the reactive gas reservoir along a length direction of the substrate and the reactive gas is temporarily stored in the reactive gas reservoir before being injected into the substrate so as to retain a high energy. In addition, a heater is provided at a portion of the reactive gas supply tube to heat the reactive gas to be supplied.

In accordance with another aspect of the present invention, there is provided a method for depositing a metal oxide on a substrate in a deposition chamber of a sputtering apparatus comprising the steps of: maintaining the deposition chamber in a state of being divided into a reaction chamber and a sputtering chamber; placing a substrate and a target in the reaction chamber and the sputtering chamber, respectively; keeping the atmosphere of the reaction chamber different from that of the sputtering chamber; reacting a metal material separated from the target in the sputtering chamber with a reactive gas present in the reaction chamber; and depositing the reaction product on the substrate. According to the method of the present invention, the transfer of the reactive gas to the metal target is minimized and thus the oxidation of the metal target is prevented, thereby enabling deposition of a metal oxide thin film on the substrate at a high rate.

According to one embodiment of the method of the present invention, the reaction chamber is formed with an exhaust port adapted to create a vacuum atmosphere in the deposition chamber so as to prevent the reactive gas from flowing backwards to the sputtering chamber. The exhaust vent is arranged at the reaction chamber to face a back surface of the substrate. The sputtering chamber is preferably arranged at a lower portion of the sputtering apparatus. The method of the present invention further comprises the step of of injecting a sputtering gas between the target material and a target cover surrounding the target material. The sputtering gas used herein is an inert gas, a reducing gas or a mixed gas thereof. The reducing gas is preferably hydrogen gas. The reactive gas used herein is oxygen, water vapor, hydrogen and a mixed gas thereof.

According to another embodiment of the method of the present invention, the metal oxide to be deposited is selected from the group consisting of MgO, CeO₂, YSZ, STO and Y₂O₃. Further, the metal oxide to be deposited may be one composite layer selected from the group consisting of CeO₂/MgO, CeO₂/YSZ/MgO, CeO₂/YSZ/CeO₂/MgO, CeO₂/MgO and CeO₂/Y2O₃.

In accordance with still another aspect of the present invention, there is provided a thin film of one metal oxide selected from the group consisting of MgO, CeO₂, YSZ, STO and Y₂O₃, prepared by the method for depositing a metal oxide according to the present invention. The thin film may be a thin film of one composite layer selected from the group consisting of CeO₂/MgO, CeO₂/YSZ/MgO, CeO₂/YSZ/CeO₂/MgO, CeO₂/MgO and CeO₂/Y2O₃.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a graph showing changes in the deposition rate of a metal oxide thin film by reactive sputtering with increasing partial pressures of oxygen;

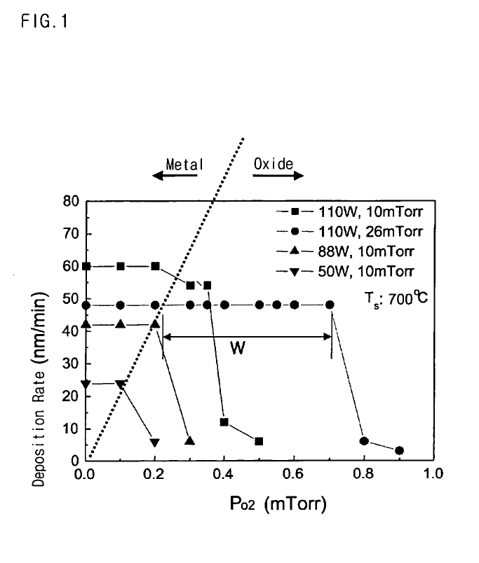

FIG. 2 is a cross-sectional view schematically showing a reactive sputtering deposition apparatus according to the present invention;

FIG. 3 is a graph showing changes in the deposition rate of a metal oxide thin film in the absence and presence of a partition plate;

FIG. 4 is a schematic view showing the location of an exhaust port in a reactive sputtering deposition apparatus of the present invention;

FIG. 5 is a graph showing changes in the deposition rate of a metal oxide thin film depending on the location of the exhaust port shown in FIG. 4;

FIG. 6 is a graph showing changes in the deposition rate of a metal oxide thin film depending on the kind of exhaust pumps;

FIG. 7 is a schematic view showing the location of an argon supply tube in a reactive sputtering deposition apparatus of the present invention;

FIG. 8 is a graph showing changes in the deposition rate of a metal oxide thin film depending on the location of the argon supply tube shown in FIG. 7;

FIG. 9 is a graph showing changes in the deposition rate of a metal oxide thin film depending on the kind of sputtering gases; and

FIG. 10 is a graph showing changes in the deposition rate of a metal oxide thin film depending on the kind of reactive gases.

### DESCRIPTION OF THE PREFERRED EMBODIMENTS

A reactive sputtering deposition apparatus and a method for depositing a metal oxide according to preferred embodiments of the present invention will now be described in more detail with reference to the accompanying drawings. However, these embodiments are given for the purpose of illustration and are not to be construed as limiting the scope of the invention.

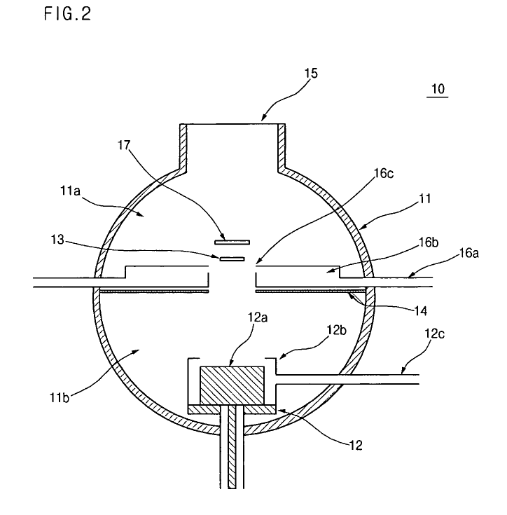

FIG. 2 is a cross-sectional view schematically showing a reactive sputtering deposition apparatus according to the present invention.

As shown in FIG. 2, the reactive sputtering deposition apparatus 10 of the present invention comprises a deposition chamber 11 for creating an inner process atmosphere of the apparatus 10, a target 12 including a metal target material to be deposited, a substrate 13 on which a reaction product of the metal material separated from the target 12 with a reactive gas is deposited, a partition plate 14 dividing the deposition chamber 11 into a reaction chamber 11a at the side of the substrate and a sputtering chamber 11b at the side of the target and provided between the target and the substrate, and an exhaust port adapted to create a vacuum atmosphere inside the deposition chamber 11.

So long as the partition plate 14 can substantially separate the substrate from the target, it is not required to divide the chamber into two complete portions. Specifically, the partition plate 14 is desirably provided in such a manner that it prevents a reactive gas from flowing backwards to the target. If desired, some spaces or holes may be formed on the partition plate. In particular, an opening is formed through a central portion of the partition plate 14 to allow the metal material separated from the target 12 to reach the substrate 13. The location and size of the opening are not particularly limited so long as the target material can be sufficiently delivered to the substrate through the opening.

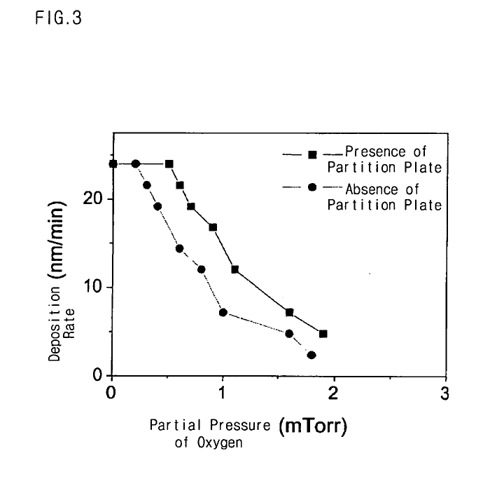

FIG. 3 is a graph showing changes in the deposition rate of a metal oxide thin film in the absence and presence of the partition plate. As shown in FIG. 3, a process window W is formed over a wider area in the presence of the partition plate. This result indicates that a metal oxide thin film is well deposited without a decrease in the deposition rate even at high partial pressures of oxygen. As is apparent from the results of FIG. 3, the partition plate 14 prevents oxygen as the reactive gas from flowing backwards to the target, allowing a metal oxide thin film to be stably deposited even at high partial pressures of oxygen.

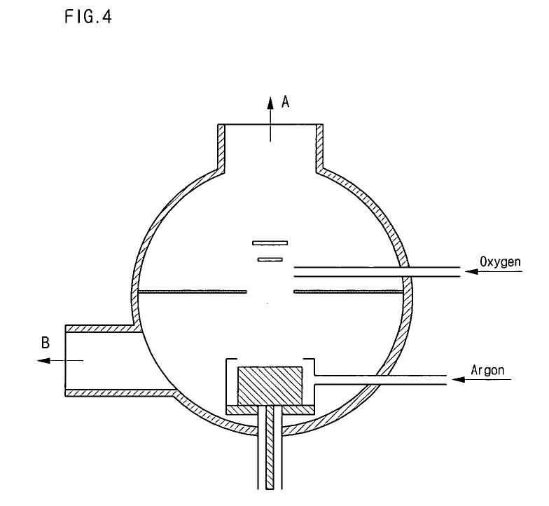

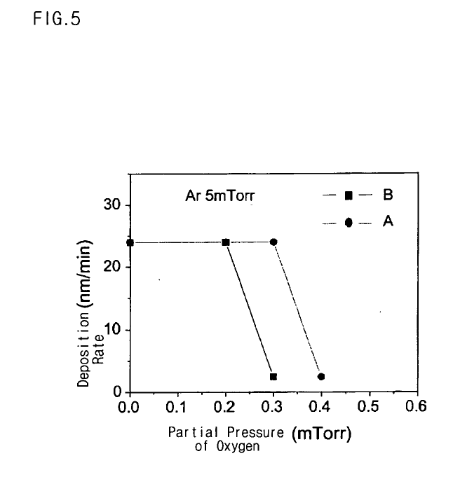

The exhaust port 15 adapted to create a vacuum atmosphere inside the chamber is preferably arranged at the reaction chamber 11a, and more preferably in a direction facing a back surface of the substrate. Since the exhaust port arranged at the reaction chamber 11a allows unreacted oxygen from the reaction with the substrate to be directly exhausted without flowing backwards to the target, oxidation of the target can be prevented. Referring again to FIG. 2, since the exhaust port and the substrate are arranged at the upper side of the target, a reactive gas heated by a heater or halogen lamp 17 provided to face a back surface of the substrate moves upwards, thus effectively preventing oxidation of the target arranged at the lower portion of the deposition chamber 11. FIG. 4 is a schematic view showing a deposition chamber in which an exhaust port (A) communicating with a pump is located at the side of the reaction chamber 11a, and an exhaust port (B) communicating with a pump is located at the side of the reaction chamber 11b. FIG. 5 is a graph showing changes in the deposition rate of a metal oxide thin film depending on the location of the exhaust port shown in FIG. 4. The results from FIG. 5 illustrate that the location of (A) shows a broader process window than the location of (B).

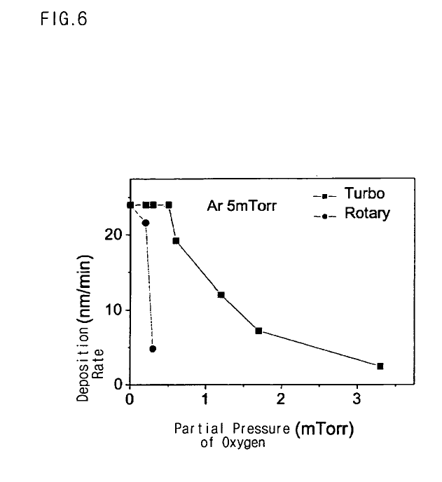

FIG. 6 is a graph showing changes in the deposition rate of a metal oxide thin film depending on the kind of pumps communicating with exhaust vents. As can be seen from FIG. 6, the case of using a rotary pump shows a broader process window than the case of using a turbo pump. That is, as the capability evacuating the deposition chamber is increased, the backward flowing of oxygen is effectively prevented.

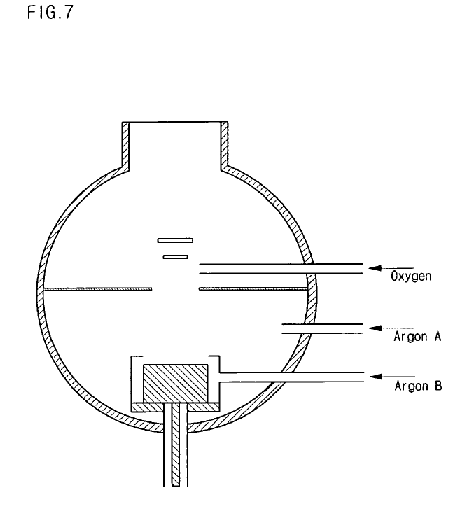

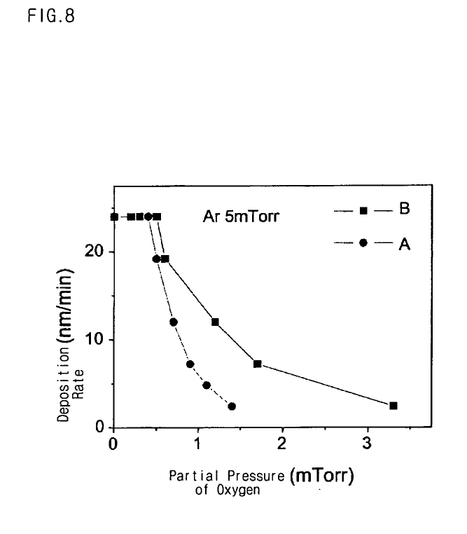

The target 12 is formed with a target material 12a and a target cover 12b surrounding the target material 12a. A sputtering gas supply tube 12b is arranged to inject a sputtering gas between the target material 12a and the cover 12b. Thus, argon gas is not directly supplied inside the deposition chamber, but supplied between the target material and the target cover to fill the vicinities of the target material with argon gas, thus minimizing oxidation of the target material due to backward flowing oxygen. FIG. 7 is a schematic view showing a deposition chamber in which an argon supply tube (A) is directly arranged, and an argon supply tube (B) is arranged such that argon is directly supplied between the target material 12a and the target cover 12b. FIG. 8 is a graph showing changes in the deposition rate of a metal oxide thin film depending on the location of the argon supply tube shown in FIG. 7. The results from FIG. 8 illustrate that the location of (A) allowing argon gas to be directly supplied between the target material 12a and the target cover 12b shows a broader process window than the location of (B).

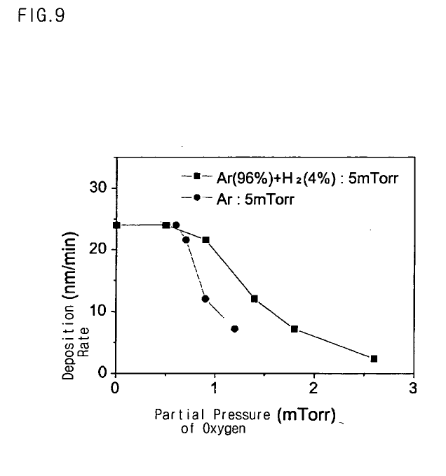

The sputtering gas is selected from inert gases, e.g., argon, reducing gases, and mixed gases thereof. The reducing gas is preferably hydrogen gas. FIG. 9 is a graph showing changes in the deposition rate of a metal oxide thin film when argon only is used as the sputtering gas, and a mixed gas of argon gas (96%) and hydrogen gas (4%) is used as the sputtering gas. The results from FIG. 9 indicate that the use of the mixed gas of argon gas (96%) and hydrogen gas (4%) shows a broader process window than the use of argon only. That is, the supply of a mixed gas with a reducing gas can minimize oxidation of the metal target material due to backward flowing oxygen.

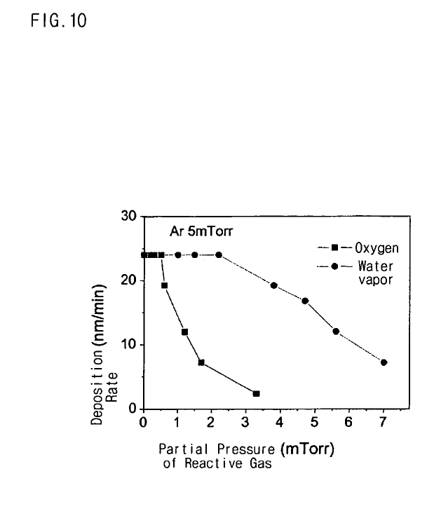

The reactive gas is selected from oxygen, water vapor and a mixed gas thereof. FIG. 10 is a graph showing changes in the deposition rate of a metal oxide thin film when oxygen and water vapor are used as reactive gases. The results from FIG. 10 indicate that the use of water vapor shows a broader process window than the use of oxygen.

The arrangement of a reactive gas supply tube 16 at the side of the substrate 13 of the partition plate 14, i.e., in the reaction chamber, induces the formation of a metal oxide film on the substrate 13 through a reaction of the substrate with the metal material separated from the target. The reactive gas supply tube 16 is connected to a reactive gas introduction pipe 16a at which a valve (not shown) is provided to control the flow of the reactive gas. The reactive gas reaches a reactive gas reservoir 16b provided inside the deposition chamber 10 through the introduction pipe. Water vapor arriving at the reactive gas reservoir is heated by a heater and generates a pressure applied to the inner walls of the gas reservoir. A 1 mm wide and 200 mm long slot 16c is formed at the nearest position of the reactive gas reservoir from the substrate 13 along a length direction of the substrate 13, and a reactive gas, such as water vapor, is injected into the substrate through the slot. When the reactive gas is water vapor, it is preferable to install a sensor (not shown) for detecting the partial pressure of water at a distance of about 30 cm apart from the substrate. In the case where the substrate temperature is 800° C. and the deposition rate is 60 nm/min., optimum partial pressure of water is 1 mTorr.

In the deposition of a metal oxide thin film using the reactive sputtering deposition apparatus, since the reactive gas is injected into the reaction chamber 11a only, which is separated from the sputtering chamber 11b by the partition plate 14, the partial pressure of the reactive gas in the reaction chamber is relatively high, compared to that in the sputtering chamber. Accordingly, the apparatus of the present invention can minimize the backward flowing of the reactive gas to the target surface, and can maximize the partial pressure of the reactive gas on the substrate surface. Further, since water vapor is injected into the vicinity of the substrate through the slot 16c formed at the reactive gas reservoir 16b, the partial pressure of water vapor on the substrate surface can be maximized. Further, an increase in the partial pressure of argon gas on the target surface can prevent the water vapor molecules from diffusing into the target surface. Further, since the argon and water vapor move upwards and are exhausted through the exhaust port, diffusion of the water vapor into the sputtering chamber can be prevented.

Hereinafter, a method for depositing a metal oxide using the reactive sputtering deposition apparatus will be explained below.

First, the sputtering apparatus is divided into the reaction chamber and the sputtering chamber in such a manner that the atmosphere of the reaction chamber is different from that of the sputtering chamber. The reaction sputtering deposition apparatus shown in FIG. 2 is preferably used. According to the reaction sputtering deposition apparatus, the transfer of the reactive gas to the metal target is minimized and thus the oxidation of the metal target is prevented, thereby enabling deposition of a metal oxide thin film on the substrate at a high rate.

In the state wherein the atmosphere of the reaction chamber is different from that of the sputtering chamber, the apparatus is evacuated through the exhaust port by the action of the pump so that it has a desired degree of vacuum, depending on processes. Next, the substrate is heated to a predetermined temperature using the heater or a radiant heat emitted from the halogen lamp, and then the reactive gas is introduced into the reaction chamber. The use of oxygen as the reaction gas causes the formation of secondary products, e.g., highly oxidative ozone and oxygen anions, and accelerates oxidation of the metal target. Accordingly, water vapor is more preferably used as the reactive gas.

After the reactive gas is introduced to stabilize the atmospheres of the deposition chamber, a sputtering gas selected from inert gases, reducing gases and mixed gases thereof is supplied to the sputtering chamber. The sputtering gas is supplied inside the target cover 12b through the sputtering gas supply tube 12c. Argon gas as an inert gas is not directly supplied inside the deposition chamber, but supplied between the target material and the target cover to fill the vicinities of the target material with argon gas, thus minimizing oxidation of the target material due to backward flowing oxygen.

A sputtering power is applied to the target to separate a target material from the target and to initiate sputtering. The separated metal material is deposited on the substrate to form a thin film thereon.

In accordance with the method of the present invention, a thin film of one metal oxide selected from MgO, CeO₂, YSZ, STO and Y₂O₃; or one composite layer selected from CeO₂/MgO, CeO₂/YSZ/MgO, CeO₂/YSZ/CeO₂/MgO, CeO₂/MgO and CeO₂/Y₂O₃, can be deposited on the substrate at a high rate.

As apparent from the above description, according to the present invention, the partition plate dividing the deposition chamber prevents oxygen as the reactive gas from flowing backwards to the target, allowing a metal oxide thin film to be stably deposited even at high partial pressures of oxygen.

Further, since the exhaust port arranged at the reaction chamber divided by the partition plate allows oxygen supplied to the substrate to be directly exhausted without flowing backwards to the target, oxidation of the target is prevented, thereby enabling deposition of a metal oxide thin film on the substrate at a high rate.

Further, since argon gas, particularly, a mixed gas with a reducing gas, as the sputtering gas is not directly supplied inside the deposition chamber, but supplied between the target material and the target cover, oxidation of the metal target material due to backward flowing oxygen can be minimized.

Further, since the use of oxygen as the reaction gas causes the formation of secondary products, e.g., highly oxidative ozone and oxygen anions, and accelerates oxidation of the metal target, water vapor is more preferably used as the reactive gas than water vapor, thereby minimizing oxidation of the target.

Moreover, since argon and water vapor move upwards and are exhausted through the exhaust port, diffusion of the water vapor into the sputtering chamber can be prevented.

Although the foregoing embodiments of the present invention have been disclosed with reference to the accompanying drawings, they are not to be construed as limiting the scope of the present invention. The scope of the present invention is defined by the claims that follow, and those skilled in the art will appreciate that various modifications and changes can be made in the spirit of the present invention. Accordingly, it is to be understood that such modifications and changes are within the scope of the present invention.

1. A reactive sputtering deposition apparatus, comprising:
a deposition chamber for creating an inner process atmosphere of the apparatus;
a target including a metal material to be deposited;
a substrate on which a reaction product of the metal material separated from the target with a reactive gas is deposited; and
a partition plate dividing the deposition chamber into a reaction chamber at the side of the substrate and a sputtering chamber at the side of the target and provided between the target and the substrate,
wherein an opening is formed through a central portion of the partition plate to allow the metal material separated from the target to reach the substrate.

2. The reactive sputtering apparatus according to claim 1, further comprising an exhaust port adapted to create a vacuum atmosphere inside the deposition chamber and arranged at the reaction chamber.

3. The reactive sputtering apparatus according to claim 2, wherein the exhaust port is arranged to face a back surface of the substrate.

4. The reactive sputtering apparatus according to claim 1, wherein the sputtering chamber is arranged beneath the reaction chamber.

5. The reactive sputtering apparatus according to claim 1, further comprising a cover surrounding the target material of the target and a sputtering gas supply tube for injecting a sputtering gas between the target material and the cover.

6. The reactive sputtering apparatus according to claim 1, wherein the sputtering gas is an inert gas, a reducing gas or a mixed gas thereof.

7. The reactive sputtering apparatus according to claim 6, wherein the reducing gas is hydrogen gas.

8. The reactive sputtering apparatus according to claim 1, further comprising a reactive gas supply tube for supplying a reactive gas to the reaction chamber so as to form a metal oxide film on the substrate through a reaction of the reactive gas with the metal material, the reactive gas supply tube being arranged at the reaction chamber.

9. The reactive sputtering apparatus according to claim 1, wherein the reactive gas is oxygen, water vapor, hydrogen and a mixed gas thereof.

10. The reactive sputtering apparatus according to claim 8, wherein the reactive gas supply tube is directed toward the substrate in a direction opposite to the target.

11. The reactive sputtering apparatus according to claim 8, further comprising a reactive gas reservoir arranged at the substrate side of the reactive gas supply tube wherein a slot having a relatively large length with respect to its width is formed at the reactive gas reservoir along a length direction of the substrate, and the reactive gas is temporarily stored in the reactive gas reservoir before being injected into the substrate so as to retain a high energy.

12. In a reactive sputtering deposition apparatus for depositing a reaction product of a metal material separated from a target with a reactive gas on a substrate, the reactive sputtering deposition apparatus, comprising:
a reactive gas supply tube for supplying the reactive gas to a reaction chamber so as to form a metal oxide film on the substrate through a reaction of the reactive gas with the metal material;
a reactive gas reservoir arranged at the substrate side of the reactive gas supply tube,
wherein a slot having a relatively large length with respect to its width is formed at the reactive gas reservoir along a length direction of the substrate, and the reactive gas is temporarily stored in the reactive gas reservoir before being injected into the substrate so as to retain a high energy; and
a reactive gas reservoir arranged at the side of the substrate of the reactive gas supply tube,
wherein the reactive gas reservoir is formed with a slot having a relatively large length with respect to its width along a length direction of the substrate so that the reactive gas is temporarily stored in the reactive gas reservoir before being injected toward the substrate and retains a high energy.

13. The reactive sputtering apparatus according to claim 12, further comprising a heater provided at a portion of the reactive gas supply tube to heat the reactive gas to be supplied.

14. The reactive sputtering apparatus according to claim 12, wherein the slot is arranged toward the substrate such that the reactive gas is injected into the substrate through the slot.

15. A method for depositing a metal oxide on a substrate in a deposition chamber of a sputtering apparatus, comprising the steps of:
maintaining the deposition chamber in a state of being divided into a reaction chamber and a sputtering chamber;
placing a substrate and a target in the reaction chamber and the sputtering chamber, respectively;
keeping the atmosphere of the reaction chamber different from that of the sputtering chamber;
reacting a metal material separated from the target in the sputtering chamber with a reactive gas present in the reaction chamber; and
depositing the reaction product on the substrate.

16. The method according to claim 15, wherein the reaction chamber is formed with an exhaust port adapted to create a vacuum atmosphere in the deposition chamber so as to prevent the reactive gas from flowing backwards to the sputtering chamber.

17. The method according to claim 16, wherein the exhaust vent is arranged at the reaction chamber to face a back surface of the substrate.

18. The method according to claim 15, wherein the sputtering chamber is arranged beneath the reaction chamber.

19. The method according to claim 15, further comprising the step of injecting a sputtering gas between the target material and a target cover surrounding the target material.

20. The method according to claim 19, wherein the sputtering gas is an inert gas, a reducing gas or a mixed gas thereof.

21. The method according to claim 20, wherein the reducing gas is hydrogen gas.

22. The method according to claim 15, wherein the reactive gas is oxygen, water vapor, hydrogen and a mixed gas thereof.

23. The method according to claim 15, wherein the metal oxide is selected from the group consisting of MgO, CeO₂, YSZ, STO and Y₂O₃.

24. The method according to claim 23, wherein the metal oxide is one composite layer selected from the group consisting of CeO₂/MgO, CeO₂/YSZ/MgO, CeO₂/YSZ/CeO₂/MgO, CeO₂/MgO and CeO₂/Y2O₃.

25. A thin film of one metal oxide selected from the group consisting of MgO, CeO₂, YSZ, STO and Y₂O₃, prepared by the method according to claim 15.

26. The thin film according to claim 25, wherein the metal oxide is one composite layer selected from the group consisting of CeO₂/MgO, CeO₂/YSZ/MgO, CeO₂/YSZ/CeO₂/MgO, CeO₂/MgO and CeO₂/Y2O₃.

27. The reactive sputtering apparatus according to claim 2, wherein the sputtering chamber is arranged beneath the reaction chamber.

28. The reactive sputtering apparatus according to claim 3, wherein the sputtering chamber is arranged beneath the reaction chamber.

29. The method according to claim 16, wherein the metal oxide is selected from the group consisting of MgO, CeO₂, YSZ, STO and Y₂O₃.

30. The method according to claim 17, wherein the metal oxide is selected from the group consisting of MgO, CeO₂, YSZ, STO and Y₂O₃.

31. The method according to claim 18, wherein the metal oxide is selected from the group consisting of MgO, CeO₂, YSZ, STO and Y₂O₃.

32. The method according to claim 19, wherein the metal oxide is selected from the group consisting of MgO, CeO₂, YSZ, STO and Y₂O₃.

33. The method according to claim 20, wherein the metal oxide is selected from the group consisting of MgO, CeO₂, YSZ, STO and Y₂O₃.

34. The method according to claim 21, wherein the metal oxide is selected from the group consisting of MgO, CeO₂, YSZ, STO and Y₂O₃.

35. The method according to claim 22, wherein the metal oxide is selected from the group consisting of MgO, CeO₂, YSZ, STO and Y₂O₃.

36. A thin film of one metal oxide selected from the group consisting of MgO, CeO₂, YSZ, STO and Y₂O₃, prepared by the method according to claim 16.

37. A thin film of one metal oxide selected from the group consisting of MgO, CeO₂, YSZ, STO and Y₂O₃, prepared by the method according to claim 17.

38. A thin film of one metal oxide selected from the group consisting of MgO, CeO₂, YSZ, STO and Y₂O₃, prepared by the method according to claim 18.

39. A thin film of one metal oxide selected from the group consisting of MgO, CeO₂, YSZ, STO and Y₂O₃, prepared by the method according to claim 19.

40. A thin film of one metal oxide selected from the group consisting of MgO, CeO₂, YSZ, STO and Y₂O₃, prepared by the method according to claim 20.

41. A thin film of one metal oxide selected from the group consisting of MgO, CeO₂, YSZ, STO and Y₂O₃, prepared by the method according to claim 21.

42. A thin film of one metal oxide selected from the group consisting of MgO, CeO₂, YSZ, STO and Y₂O₃, prepared by the method according to claim 22.
